(19) United States
(12) Patent Application Publication
(10) Pub. No.: US 2025/0351357 A1
(43) Pub. Date: Nov. 13, 2025

(54) THREE-DIMENTIONAL PILLAR TYPE CAPACITIVE IN-MEMORY COMPUTING DEVICE, METHOD OF MANUFACTURING THE SAME AND IN-MEMORY COMPUTING DEVICE USING THE SAME

(71) Applicant: SK hynix Inc., Gyeonggi-do (KR)

(72) Inventor: Choong Ki KIM, Gyeonggi-do (KR)

(21) Appl. No.: 19/203,202

(22) Filed: May 9, 2025

(30) Foreign Application Priority Data
May 9, 2024 (KR) 10-2024-0061077
Dec. 10, 2024 (KR) 10-2024-0182983

(51) Int. Cl. H10B 43/30; H10B 43/10; H10B 43/20; H10B 43/40; H10D 30/01; H10D 30/69

(52) U.S. Cl. CPC H10B 43/30; H10B 43/10; H10B 43/20; H10B 43/40; H10D 30/0413; H10D 30/69

(57) ABSTRACT

A three-dimensional pillar type capacitive in-memory computing device may include a first wiring layer, a junction layer formed on the first wiring layer in a first direction, a channel including a pillar structure formed on the junction layer in the first direction, a charge storage layer configured to surround an upper surface and an outer surface of the channel, a charge transfer layer formed on the charge storage layer in the first direction, and a second wiring layer formed on the charge transfer layer in the first direction.

### CROSS-REFERENCES TO RELATED APPLICATION

The present application claims priority under 35 U.S.C. § 119(a) to Korean application number 10-2024-0061077, filed on May 9, 2024, and Korean patent application number 10-2024-0182983, filed on Dec. 10, 2024, which are incorporated herein by reference in their entirety.

### BACKGROUND

### 1. Technical Field

Embodiments of the present disclosure relate generally to a semiconductor device, and more particularly to a three-dimensional pillar type capacitive in-memory computing device, a method of manufacturing the same, and an in-memory computing device utilizing the same.

### 2. Related Art

A growing interest and importance of artificial intelligence (hereinafter, AI) applications and big data analytics is driving an explosion in demand for semiconductor devices for computing and storing massive amounts of data.

Main computational methods required in the AI applications may include matrix multiplication operations. Recently, in-memory computing techniques have been studied to minimize a bottleneck of data movements and power consumption by performing matrix multiplication operations within an array of memory cells.

In the learning and inference process of the AI applications, latency and energy required for matrix multiplication operations may be closely related to the size of the in-memory computing device.

### SUMMARY

According to embodiments of the present disclosure, there is provided, a three-dimensional (3D) pillar type capacitive in-memory computing device. The 3D pillar type capacitive in-memory computing device may include a first wiring layer, a junction layer, a pillar type channel, a charge storage layer, a charge transfer layer and a second wiring layer. The junction layer may be formed on a portion of the first wiring layer in a first direction. The pillar type channel may be formed on a portion of the junction layer in the first direction. The charge storage layer may be configured to entirely surround an upper surface of the pillar type channel in the first direction and an outer surface of the pillar type channel. The charge transfer layer may be formed on a portion of the charge storage layer in the first direction. The second wiring layer may be formed on the charge transfer layer in the first direction.

According to an embodiment of the present disclosure, there is provided, a three-dimensional (3D) pillar type capacitive in-memory computing device. The 3D pillar type capacitive in-memory computing device may include a first wiring layer, a junction layer, a pillar type channel, a current blocking layer, a charge storage layer and a second wiring layer. The junction layer may be formed on a portion of the first wiring layer in a first direction. The pillar type channel may be formed on a portion of the junction layer in the first direction. The current blocking layer may be configured to entirely surround an upper surface of the pillar type channel in the first direction and an outer circumferential surface of the pillar type channel. The charge storage layer may be configured to entirely surround an upper surface of the current blocking layer in the first direction and an outer surface of the current blocking layer. The second wiring layer may be formed on a portion of the charge storage layer in the first direction.

According to an embodiment of the present disclosure, there is provided a method of manufacturing a 3D pillar type capacitive in-memory computing device. In the method of manufacturing the 3D pillar type capacitive in-memory computing device, a first wiring layer may be formed on a substrate. A junction layer may be formed on a portion of the first wiring layer in a first direction. A pillar type channel may be formed on a portion of the junction layer in the first direction. A charge storage layer may be formed to entirely surround a surface of the pillar type channel. A charge transfer layer may be formed on a portion of the charge storage layer in the first direction. A second wiring layer may be formed on a portion of the charge transfer layer in the first direction.

According to an embodiment of the present disclosure, there is provided, a computing device using a 3D pillar type capacitive in-memory computing device. The computing device may include a logic circuit, a memory cell array, a row decoder, a pre-amplifier, a multiplexer and an analog/digital (A/D) converter. The memory cell array may include a plurality of unit memory cells connected between a plurality of word lines and a plurality of bit lines. The row decoder may convert an externally provided digital input signal to an analog signal and applies the analog signal to a selected word line in accordance with a control of the logic circuit. The pre-amplifier may amplify an output signal applied to the bit line in accordance with a control of the logic circuit. The multiplexer may select at least one of the plurality of bit lines in accordance with a control of the logic circuit. The A/D converter may sense an analog signal applied to a selected bit line. The A/D converter may convert the analog signal into a digital signal. The A/D converter may then output the digital signal. The unit memory cell may include a first wiring layer, a junction layer, a pillar type channel, a charge storage layer, a charge transfer layer and a second wiring layer. The junction layer may be formed on a portion of the first wiring layer in a first direction. The pillar type channel may be formed on a portion of the junction layer in the first direction. The charge storage layer may be configured to entirely surround an upper surface of the pillar type channel in the first direction and an outer circumferential surface of the pillar type channel. The charge transfer layer may be formed on a portion of the charge storage layer in the first direction. The second wiring layer may be formed on a portion of the charge transfer layer in the first direction.

### BRIEF DESCRIPTION OF THE DRAWINGS

The above and other aspects, features and advantages of the embodiments of the present disclosure will be more easily understood from the following detailed description taken in conjunction with the accompanying drawings, in which:

FIG. 1 is a perspective view illustrating an in-memory computing device in accordance with an embodiment of the present disclosure;

FIGS. 2 and 3 are cross-sectional views illustrating an in-memory computing device in accordance with an embodiment of the present disclosure;

FIGS. 4 and 5 are cross-sectional views illustrating concepts of operation of an in-memory computing device in accordance with an embodiment of the present disclosure;

FIG. 6 is a view illustrating voltage and capacitance characteristics of an in-memory computing device in accordance with an embodiment of the present disclosure;

FIG. 7 is a view illustrating electron density by state of an in-memory computing device in accordance with an embodiment of the present disclosure;

FIG. 8A and FIG. 8B are views illustrating capacitance characteristics as a function of channel length of an in-memory computing device in accordance with an embodiment of the present disclosure;

FIG. 9A and FIG. 9B are simplified schematics illustrating capacitance characteristics along a charge storage layer length of an in-memory computing device in accordance with an embodiment of the present disclosure;

FIG. 10 is a view illustrating an occupying area of a unit in-memory computing device in accordance with an embodiment of the present disclosure;

FIG. 11A to FIG. 23C are simplified schematic views illustrating a method of manufacturing an in-memory computing device in accordance with an embodiment of the present disclosure;

FIGS. 24 to 26 are cross-sectional views illustrating an in-memory computing device in accordance with an embodiment of the present disclosure; and

FIG. 27 is a view illustrating a computing device using an in-memory computing device in accordance with an embodiment of the present disclosure.

### DETAILED DESCRIPTION

The advantages and features of the present invention, and methods of achieving them, will become apparent upon reference to the embodiments described in detail with reference to the accompanying drawings. The invention, however, is not limited to the embodiments disclosed herein, but may be embodied in many different forms, and these embodiments are provided merely to make the present disclosure complete, and to give those of ordinary skill in the art a complete idea of the scope of the invention, which is defined by the claims. The dimensions and relative sizes of the layers and regions in the drawings may be exaggerated for clarity of description. Throughout the specification, like reference numerals refer to like components.

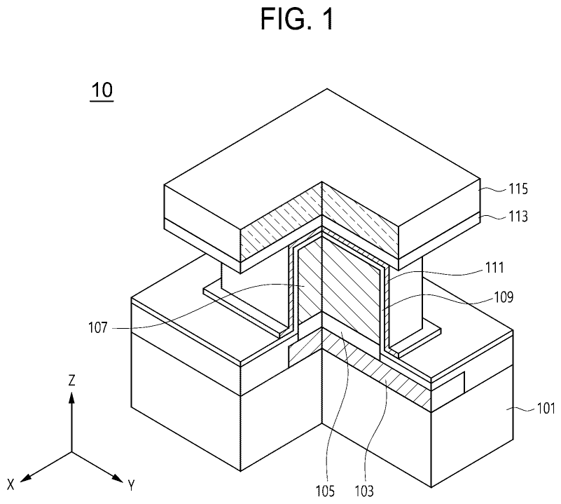

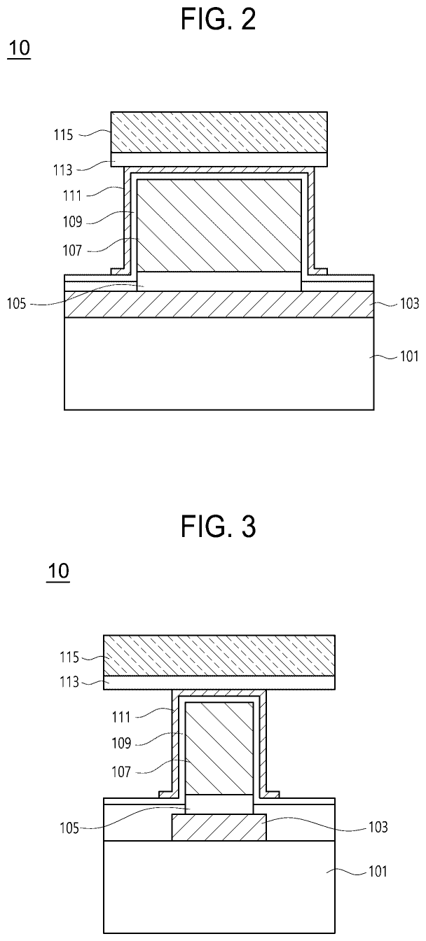

FIG. 1 is a perspective view illustrating an in-memory computing device in accordance with an embodiment of the present disclosure, FIG. 2 is a cross-sectional view illustrating of an in-memory computing device along an X-direction in accordance with an example embodiment of the present disclosure, and FIG. 3 is a cross-sectional view illustrating an in-memory computing device along a Y-direction in accordance with an embodiment of the present disclosure.

Referring to FIGS. 1 to 3, an in-memory computing device 10 may include a first wiring layer 103, a junction layer 105 formed over the first wiring layer 103, a channel 107 formed over the junction layer 105, a charge storage layer 111, a charge transfer layer 113 and a second wiring layer 115. The first wiring layer 103 may be formed on a substrate 101 in a first direction, such as a vertical (Z) direction. The junction layer 105 may be formed over the first wiring layer 103 in the first direction. The junction layer 105 may be formed on a portion of the first wiring layer 103. The channel 107 may be formed over the junction layer 105 in the first direction. The channel 107 may be formed on the junction layer 105 in the first direction. For example, the channel 107 may include a pillar structure extended in the first direction. The channel 107 and the junction layer 105 may form a pillar structure in the first direction. The charge storage layer 111 may entirely surround an upper surface and an outer surface of the channel 107. The charge transfer layer 113 may be formed on the charge storage layer 111 on the upper surface of the channel 107 in the first direction. The second wiring layer 115 may be formed on the charge transfer layer 113 in the first direction.

In an embodiment of the present disclosure, a current blocking layer 109 may be formed between the channel 107 and the charge storage layer 111, however, the embodiment may not be limited thereto.

In an embodiment of the present disclosure, the first wiring layer 103 may include a first signal line, such as, for example, a bit line.

In an embodiment of the present disclosure, the first wiring layer 103 may include a silicon-base material, a metal-base material, or a combination thereof. The first wiring layer 103 may include a polysilicon, a metal, a metal nitride, a metal silicide, or a combination thereof. The first wiring layer 103 may include polysilicon, titanium nitride, tungsten, or a combination thereof. In an embodiment, the first wiring layer 103 may include a stack of titanium nitride and tungsten.

For example, the junction layer 105 may include a polysilicon layer with N-type dopants.

Alternately, the channel 107 may include an undoped polysilicon layer.

In an embodiment of the present disclosure, the current blocking layer 109 may include a high-K dielectric layer. For example, a dielectric constant (K) of the high-K dielectric layer may be greater than about 30.

In an embodiment, the current blocking layer 109 may include hafnium oxide (HfO₂), zirconium oxide (ZrO₂), aluminum oxide (Al₂O₃), lanthanum oxide (La₂O₃) titanium oxide (TiO₂), tantalum oxide (Ta₂O₅), niobium oxide (NB₂O₅), or strontium titanium oxide (SrTiO₃). Alternatively, the current blocking layer 109 may be a composite layer comprising two or more layers of the aforementioned high dielectric materials.

In an embodiment, the charge storage layer 111 may include a metal material.

In an embodiment, the charge transfer layer 113 may include the high-K dielectric layer having a dielectric constant at a set level, e.g., greater than about 30.

In embodiment, the charge transfer layer 113 may comprise hafnium oxide (HfO₂), zirconium oxide (ZrO₂), aluminum oxide (Al₂O₃), lanthanum oxide (La₂O₃) titanium oxide (TiO₂), tantalum oxide (Ta₂O₅), niobium oxide (NB₂O₅), or strontium titanium oxide (SrTiO₃). Alternatively, the charge transfer layer 113 may be a composite layer comprising two or more layers of the aforementioned high dielectric materials.

In an embodiment of the present disclosure, the second wiring layer 115 may be a second signal line. The second signal line may be a word line.

In an embodiment of the present disclosure, the second wiring layer 115 may include a metal-base material, a semiconductor material, or a combination thereof. The second wiring layer 115 may include titanium nitride, tungsten, polysilicon, or a combination thereof. The second wiring layer 115 may include a stack of titanium nitride and tungsten stacked sequentially.

In an embodiment of the present disclosure, the second wiring layer 115 may be formed only on an upper end of the channel 107, and at the same time ensure excellent current transfer performance.

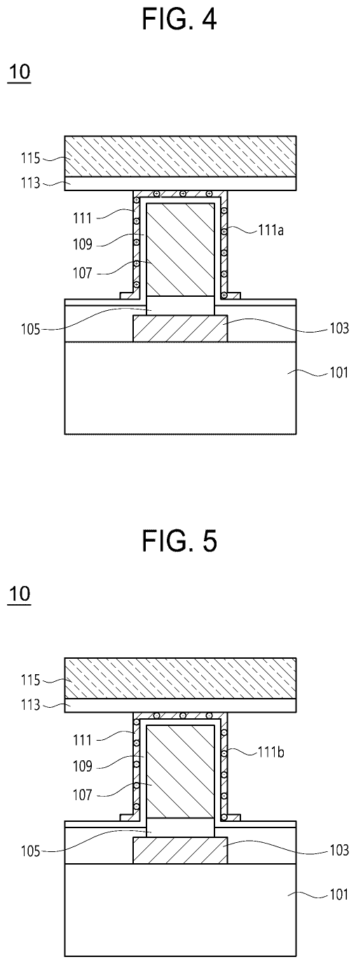

FIGS. 4 and 5 are cross-sectional views illustrating the technical concepts of the operation of an in-memory computing device in accordance with embodiments of the present disclosure. FIG. 4 depicts an on state and FIG. 5 depicts an off state.

The in-memory computing device 10 of an embodiment may include a single junction layer 105. Thus, an operating voltage may be applied to the second wiring layer 115 to inject charges into the charge transfer layer 113, thereby causing polarization.

Due to a capacitive coupling effect between the current blocking layer 109 and the charge transfer layer 113, the voltage in the charge storage layer 111 may be dependent on the operating voltage applied to the second wiring layer 115.

In a program operation, when a voltage over a certain level may be applied to the second wiring layer 115 to generate a burst current in the charge transfer layer 113, an abrupt charge injection may be generated from the second wiring layer 115 to the charge storage layer 111 shown in FIG. 4. A numeral reference 111a of FIG. 4 indicates the abrupt charges.

Because the charge storage layer 111 may be floated, after the abrupt charge injection, the charges 111a may accumulate in the charge storage layer 111. Thus, a capacitance between the second wiring layer 115 and the first wiring layer 103 may be maximized by the accumulated charges 111a.

FIG. 5 may show the off state after the program operation.

Through an erasing operation, a depletion layer of negative charge 111b may be formed in the charge storage layer 111, thereby reducing the capacitance between the second wiring layer 115 and the first wiring layer 103.

The difference between an on-state capacitance value Cₒₙ shown in FIG. 4 and an off-state capacitance value C_{off} shown in FIG. may determine a memory window of the in-memory computing device 10.

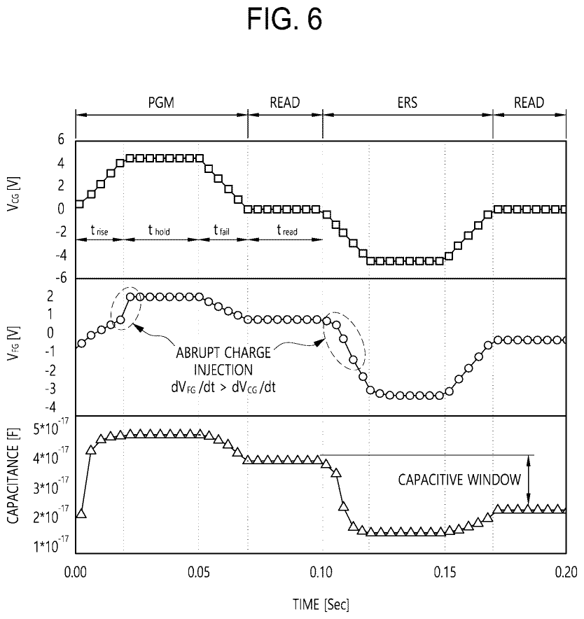

FIG. 6 is a view illustrating voltage and capacitance characteristics of an in-memory computing device in accordance with an embodiment of the present disclosure.

Referring to FIG. 6, a voltage V_{CG} applied to second wiring layer 115, a voltage V_{FG} of the charge storage layer 111 and capacitance characteristics during a program operation PGM, a read operation Read, and an erase operation ERA may be shown.

It can be seen that when the program voltage and the erase voltage may be applied to about +4V and about −3V for about 30 ms, respectively, it has a capacitive window of more than about 2, i.e., a memory window.

When an abrupt charge injection may be generated, dV_{FG}/dt may be greater than dV_{CG}/dt. This means that when a voltage over a certain level may be applied to the second wiring layer 115, the voltage V_{FG} of the charge storage layer 111, which follows the voltage of the second wiring layer 115, may increase rapidly, resulting in a value of dV_{FG}/dV_{CG} greater than about 1.

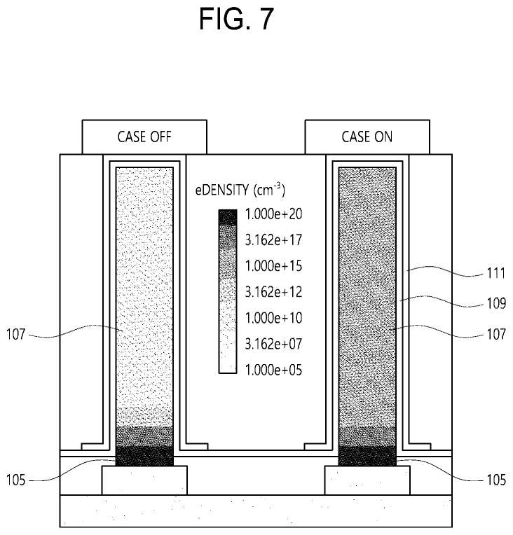

FIG. 7 is a view illustrating electron density by state of an in-memory computing device in accordance with an embodiment of the present disclosure.

An inversion layer (not shown) may be formed between the current blocking layer 109 and the pillar type channel 107 during a read operation, after a program operation (CASE ON). Thus, the pillar type channel 107 may have an overall high electron density due to the inversion layer. In contrast, the electron density of the channel 107 in an erased operation (CASE OFF) may be only measured to be high near the junction layer 105.

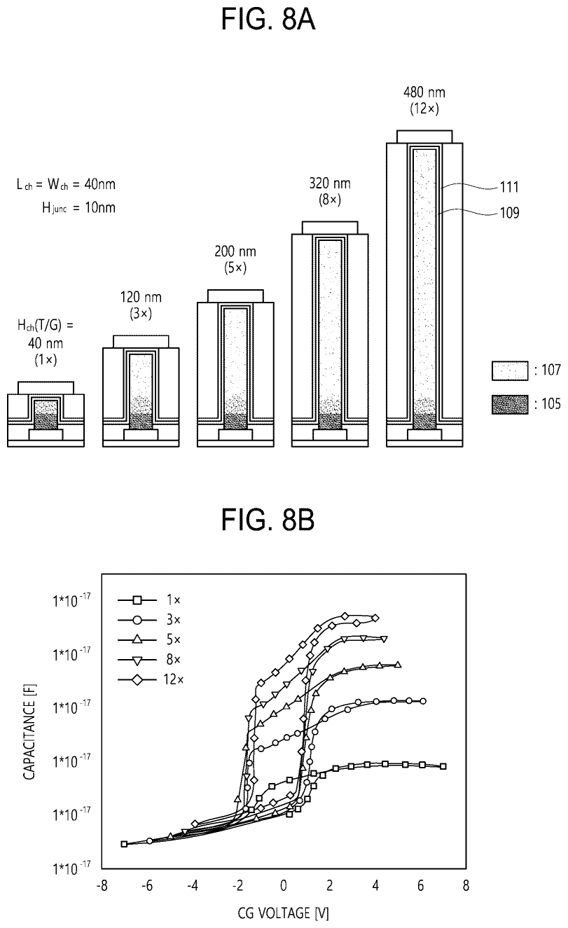

FIG. 8A and FIG. 8B are a view illustrating capacitance characteristics as a function of the channel length of an in-memory computing device in accordance with an embodiment of the present disclosure.

FIG. 8A is a cross-sectional view illustrating an in-memory computing device having a junction layer 105 with a height H_{junc} of about 10 nm and a channel length that is 1×, 3×, 5×, 8×, or 12× the channel length H_{ch} (T/G) when a target channel length H_{ch} (T/G) may be about 40 nm.

FIG. 8B is a graph showing on state capacitances according to variation of a CG voltage applied to the second wiring layer 115.

Referring to FIG. 8B, the on-state capacitance may significantly increase as a channel length increases. The off-state capacitance (not shown) may also increase, but may have a very slow increase trend compared to the on-state capacitance. Thus, increasing the channel length of the pillar-type channel 107 may provide a large memory window.

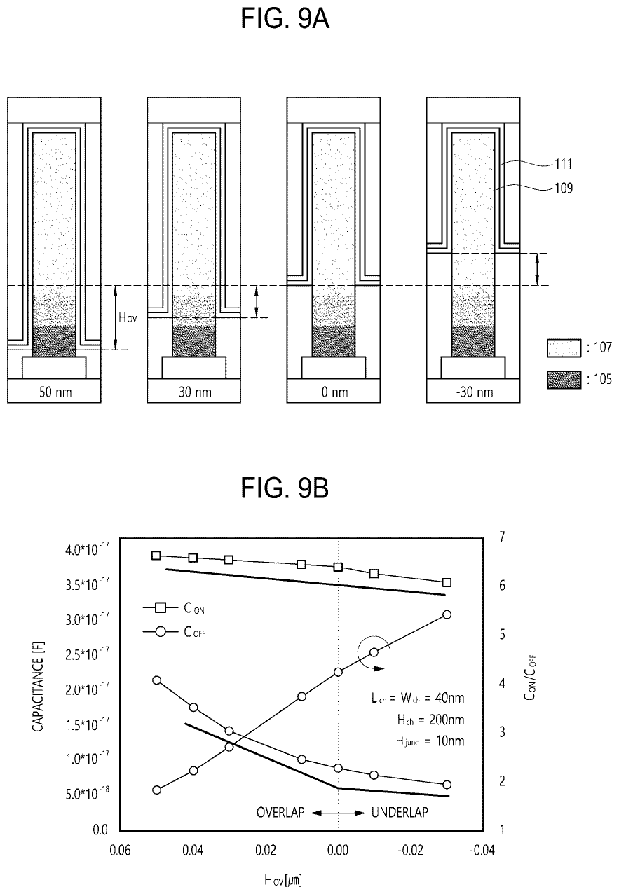

FIG. 9A and FIG. 9B illustrate capacitance characteristics along a charge storage layer length of an in-memory computing device in accordance with an embodiment of the present disclosure.

FIG. 9A shows cross-sectional views of the in-memory computing devices having different overlap lengths Hₒᵥ of the channel 107 and the junction layer 105. For example, FIG. 9A shows cases where overlap lengths Hₒᵥ are 50 nm, 30 nm, 0 nm and −30 nm.

FIG. 9B shows a ratio Cₒₙ/C_{off} when the in-memory computing device includes 40 nm of the channel width W_{ch}, 40 nm of the channel length H_{ch}, and 10 nm of length of the junction layer H_{junc}. For example, the on-state capacitance Cₒₙ may be determined by the overlap lengths Hₒᵥ of the channel 107 and the junction layer 105.

Referring to FIG. 9A and FIG. 9B, as the overlap length Hₒᵥ, decreases, the capacitance ratio Cₒₙ/C_{off} increases.

For example, the off-state capacitance C_{off} has a minimum value when the overlap length Hₒᵥ is 0 nm. That is, when a bottom portion of the charge storage layer 111 is equal to an upper portion of the junction layer 105, a large memory window may be obtained, even though the on-state capacitance Cₒₙ decreases.

However, if the charge storage layer 111 is underlapped rather than overlapped with the junction layer 105 (for example, the overlap length Hₒᵥ is −30 nm in FIG. 9A), the off-state capacitance C_{off} may no longer decrease rapidly.

Therefore, it may be important to determine the overlap length Hₒᵥ to maximize the on-state capacitance Con while ensuring the capacitance ratio Cₒₙ/C_{off}.

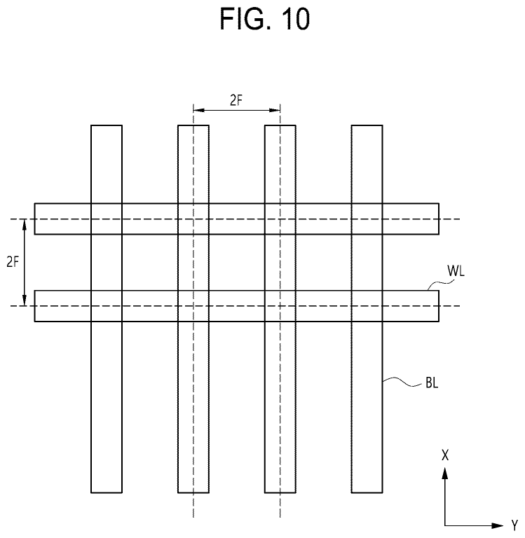

FIG. 10 is a view illustrating an occupying area of a unit cell of an in-memory computing device in accordance with an embodiment of the present disclosure.

Referring to FIG. 10, an in-memory computing device 10 may include a plurality of word lines WL and a plurality of bit lines BL. The word lines WL may extend parallel along a second direction. The word lines WL may be arranged to have 2 pitch sizes (2F, here “F” is a minimum feature size). For example, the word line WL may be the first wiring layer 103. The bit lines BL may extend parallel along a third direction (Y) perpendicular to the first direction. The bit lines may be arranged to have 2 pitch sizes (2F). For example, the bit line BL may be the second wiring layer 115. The pitch may be a minimum feature size. A unit cell may be formed at an intersection of the word line and the bit line. Thus, an occupying area of the unit cell may be 4F22.

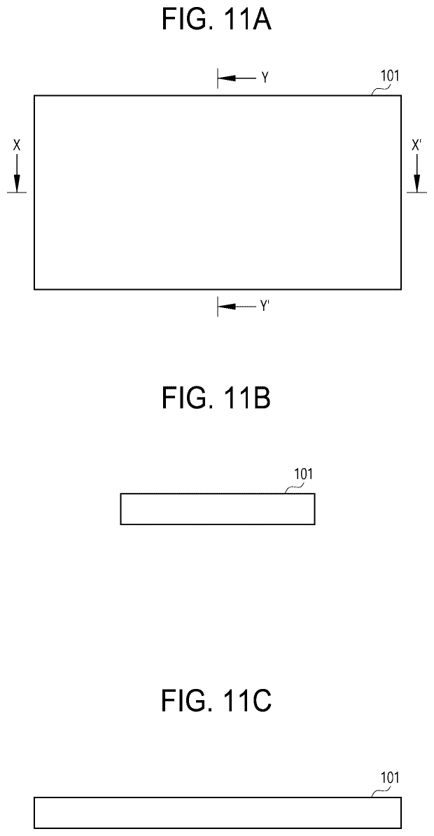

FIG. 11A to FIG. 23C are simplified schematic views illustrating a method of fabricating an in-memory computing device in accordance with an embodiment of the present disclosure.

FIG. 11A to FIG. 23A are plan views of the in-memory computing device. FIG. 11B to FIG. 23B are cross-sectional views of the Y-Y′ portion of the in-memory computing device. FIGS. 11C to FIG. 23C are cross-sectional views of the X-X′ portion of the in-memory computing device.

Referring to FIGS. 11A to 11C, a substrate 101 may be prepared.

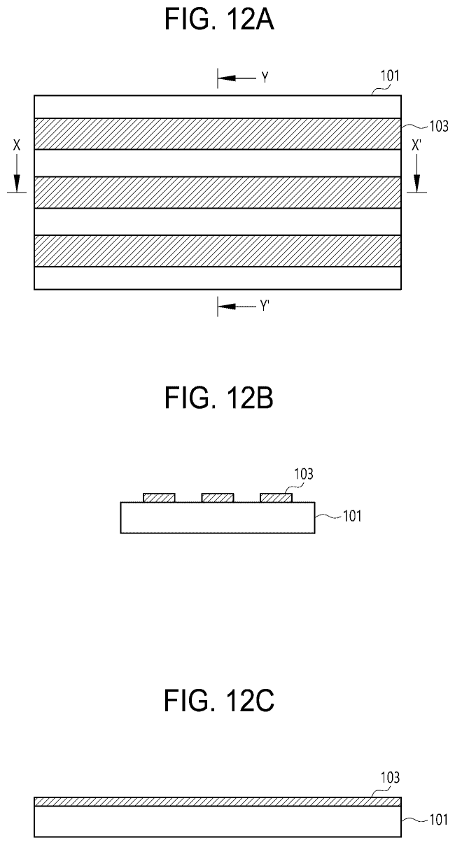

As shown in FIGS. 12A to 12C, a first wiring material layer may be formed on the substrate 101. The first wiring material layer may then be patterned to form a plurality of first wiring layers 103 which are spaced apart from each other.

The first wiring layer 103 may include a silicon-base material, a metal-base material, or a combination thereof. The first wiring layer 103 may include a polysilicon, a metal, a metal nitride, a metal silicide, or a combination thereof. The first wiring layer 103 may include polysilicon, titanium nitride, tungsten, or a combination thereof. The first wiring layer 103 may include a stack of titanium nitride and tungsten.

The first wiring layers 103 may have a line shape extending in a second direction X, and a certain width and may be spaced apart in a third direction Y tilted at a certain angle to the first direction X. For example, the first wiring layer 103 may be a bit line.

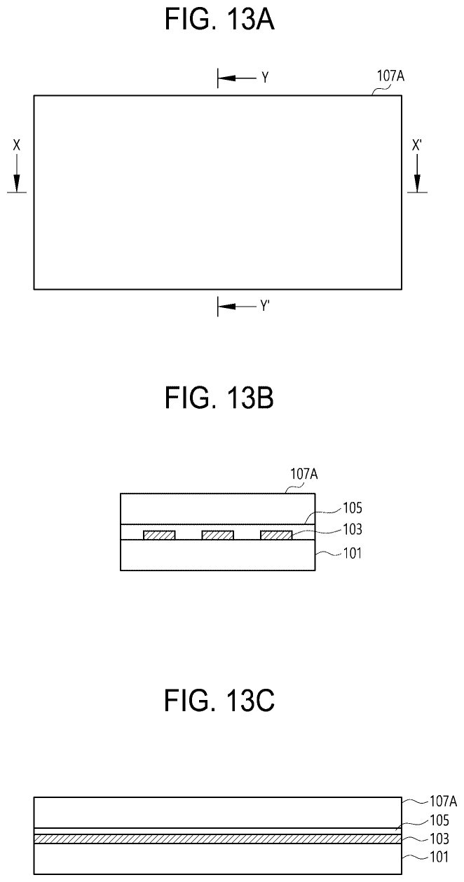

Referring to FIGS. 13A to 13C, a polysilicon layer may be formed over an overall structure in which the first wiring layer 103 is formed. The polysilicon layer may be doped with N type dopants to form a junction layer 105.

An undoped polysilicon layer 107A may be formed on the junction layer 105 at a set thickness. A thickness of the undoped polysilicon layer 107A may be greater than a thickness of the junction layer 105.

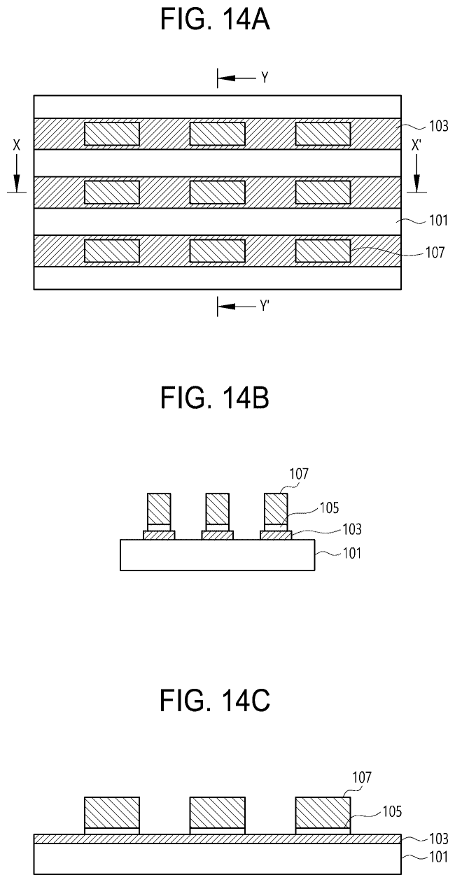

Referring to FIGS. 14A to 14C, the polysilicon layer 107A and the junction layer 105 may be patterned into a pillar shape to form a plurality of spaced apart channels 107. For example, each of the channels 107 may include a pillar structure.

Furthermore, each pair of a channel 107 and its corresponding junction layer 105 may have a pillar structure. Each pillar structure including a channel 107 and a junction layer 105 may be formed over a first wiring layer 103.

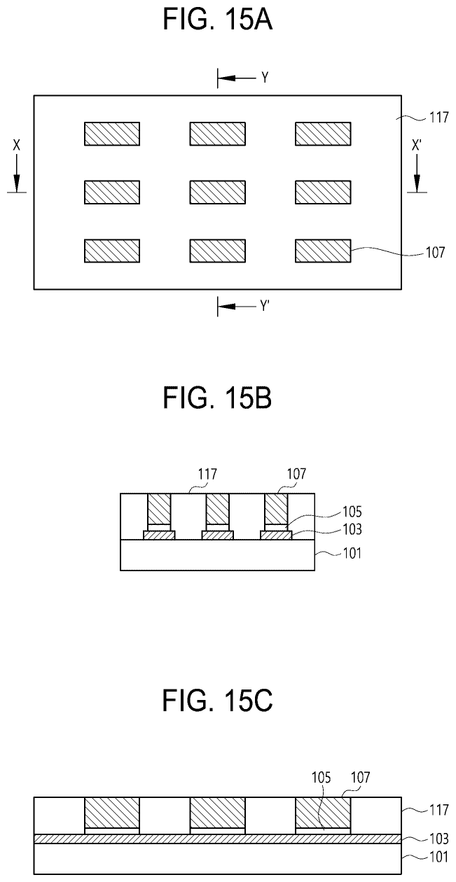

As shown in FIGS. 15A to 15C, a first insulating interlayer 117 may be formed over the substrate 101 to cover the pillar structures. The first insulating interlayer 117 may then be planarized to expose an upper surface of each of the channels 107. In an embodiment of the present disclosure, the first insulating interlayer 117 may be formed using a low-K material.

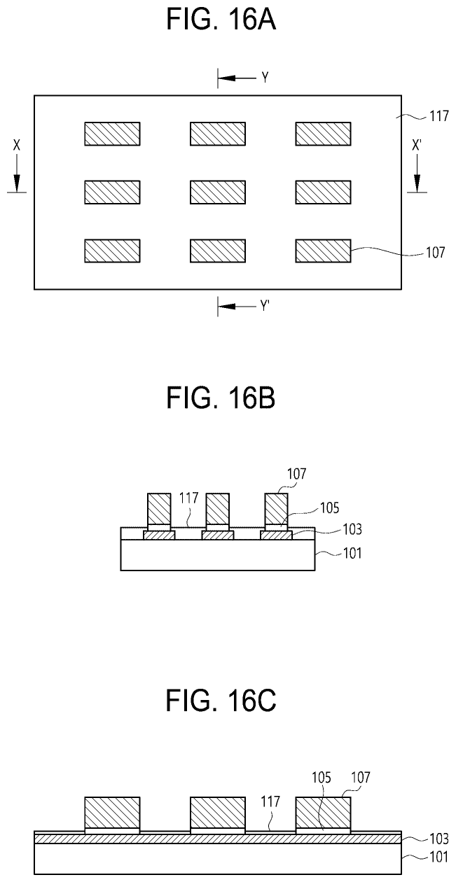

Referring to FIGS. 16A to 16C, the first insulating interlayer 117 may be further etched back so that the neighboring first wiring layers 103 and the junction layers 105 may be insulated. Accordingly, the junction layers 105 adjacently arranged in the second direction (X) may be electrically isolated by the first insulating interlayer 117. The first wiring layer 103 adjacently arranged in third direction (Y) may be electrically isolated by the first insulating interlayer 117.

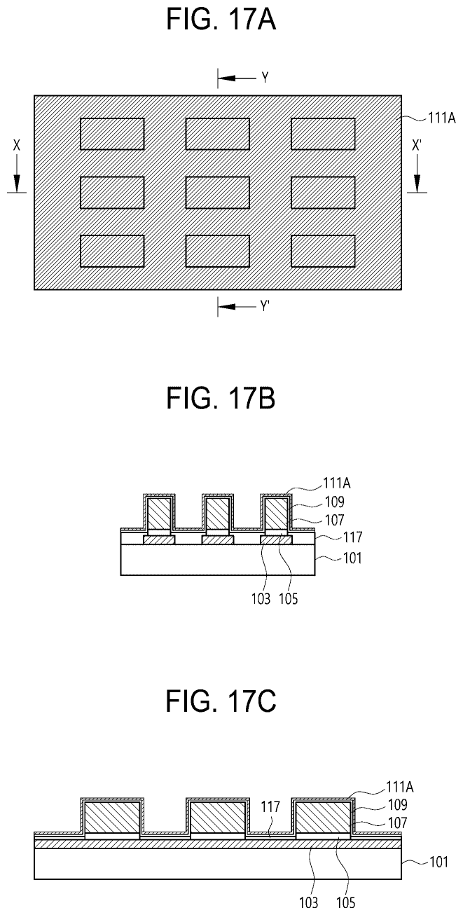

Referring to FIGS. 17A to 17C, a current blocking layer 109 and a conductive layer 111A may be formed on the channels 107 and the first insulating interlayer 117. In an embodiment of the present disclosure, the current blocking layer 109 may include a high-K material. For example, the dielectric constant of the high-K material may be higher than 30. In an embodiment of the present disclosure, the conductive layer 111A may include a metal material.

In an embodiment of the present disclosure, the current blocking layer 109 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (NB₂O₅), or strontium titanium oxide SrTiO₃. Alternatively, the current blocking layer 109 may be a composite layer including two or more layers of the aforementioned high dielectric materials.

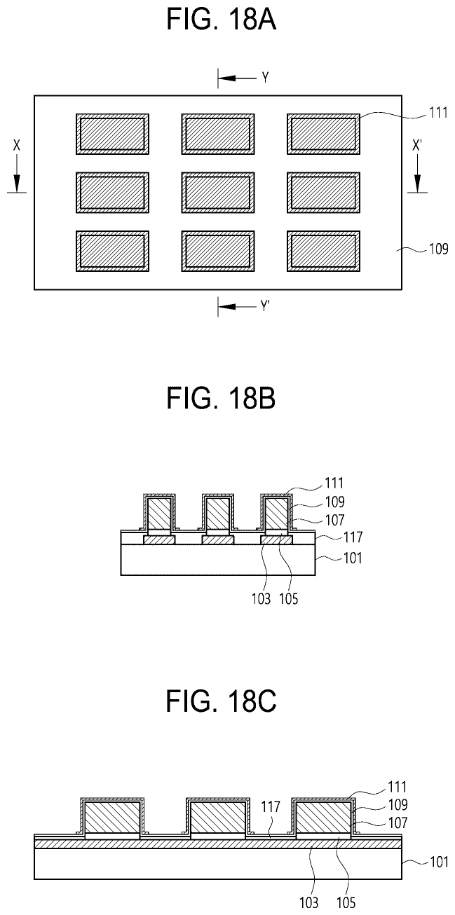

Then, as shown in FIGS. 18A to 18C, the conductive layer 111A may be patterned to expose the current blocking layer 109 located on the first insulating interlayer 117 thereby forming the charge storage layers 111 which cover the channels 107.

Accordingly, the upper surface and the outer surface of each of the pillar type channels 107 may be covered by the current blocking layer 109 and the charge storage layer 111.

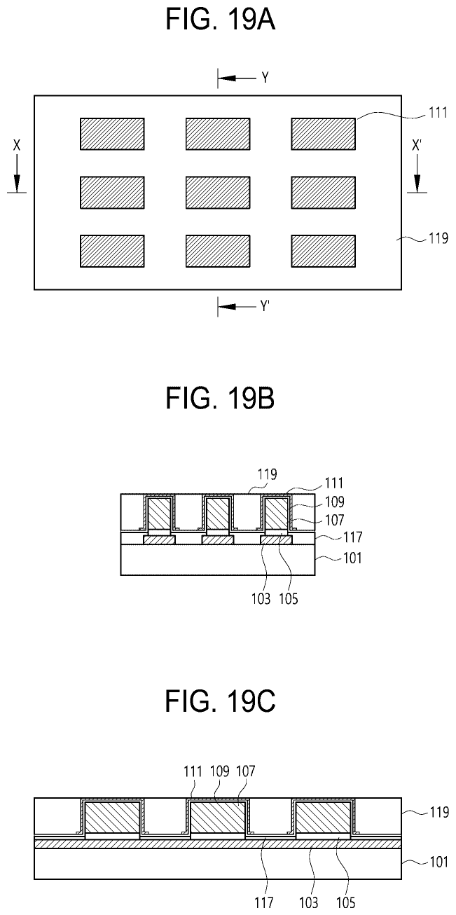

As shown in FIGS. 19A to 19C, a second insulating interlayer 119 may be formed over the structure of FIGS. 18A, 18B, and 18C including the charge storage layer 111. The second insulating interlayer 119 may then be planarized to expose the charge storage layer 111 that is formed on the top surface of each of the channels 107.

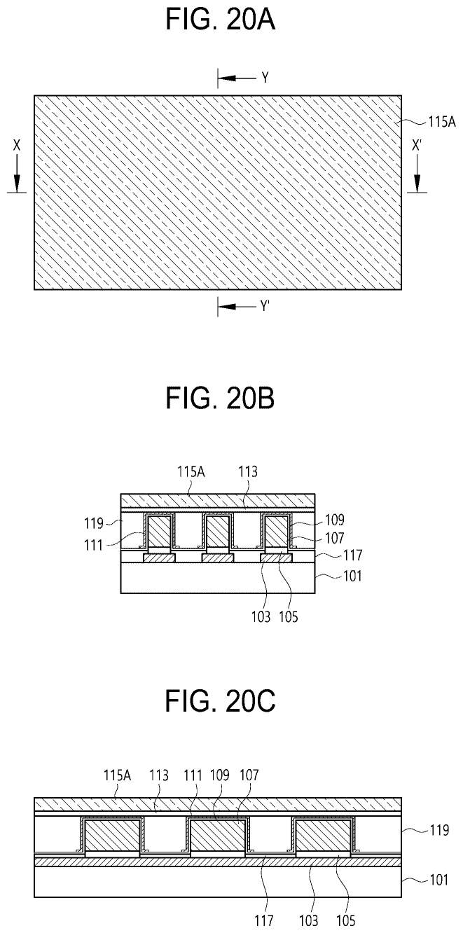

Referring to FIGS. 20A to 20C, a charge transfer layer 113 and a second wiring material layer 115A may be formed on the second insulating interlayer 119 and the charge storage layer 111.

In an embodiment of the present disclosure, the charge transfer layer 113 may include a high-K material including a dielectric constant being higher than 30. In an embodiment of the present disclosure, the charge transfer layer 113 may include hafnium oxide (HfO₂), zirconium oxide (ZrO₂), aluminum oxide (Al₂O₃), lanthanum oxide (La₂O₃) titanium oxide (TiO₂), tantalum oxide (Ta₂O₅), niobium oxide (NB₂O₅), or strontium titanium oxide (SrTiO₃). For example, the charge transfer layer 113 may be a composite layer including two or more layers of the aforementioned high dielectric materials.

The second wiring material layer 115A may include a metal-base material, a semiconductor material, or a combination thereof. The second wiring material layer 115A may include titanium nitride, tungsten, polysilicon, or a combination thereof. The second wiring material layer 115A may include a stack of titanium nitride and tungsten laminated sequentially.

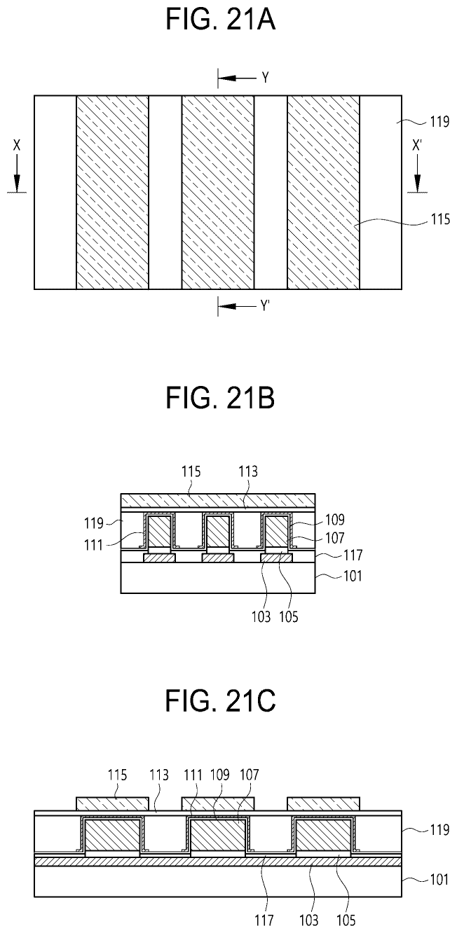

Referring to FIGS. 21A to 21C, the second wiring material layer 115A and the charge transfer layer 113 may be patterned to extend along the second direction Y, such that the charge transfer layer 113 and a second wiring layer 115 may be formed over the channel 107. For example, the second wiring layer 115 may include a word line.

In an embodiment of the present disclosure, the second wiring layer 115 may be formed extending in the second direction Y and having a certain width and being spaced apart in the first direction X. Accordingly, the second insulating interlayer 119 between the second wiring layers 115 may be exposed.

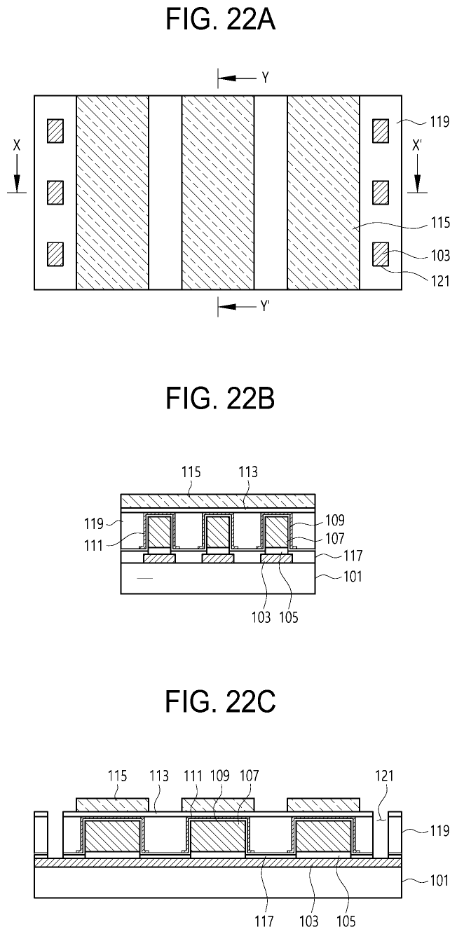

Referring to FIGS. 22A to 22C, at least one first wiring layer contact hole 121 is formed in the second insulating interlayer 119, to expose the first wiring layer 103 of edge portions. For example, at least one end of the first wiring layers 103 is exposed by the first wiring layer contact hole 121.

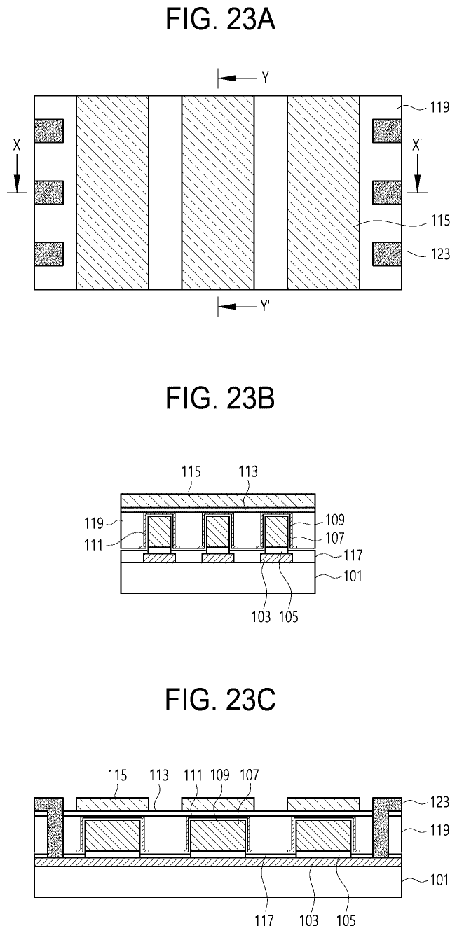

As shown in FIGS. 23A to 23C, a conductive layer 123 may be formed over the substrate 101 to fill the first wiring layer contact hole 121. For example, the first wiring layer 103 may receive an operating voltage by the conductive layer 123.

In this way, the first wiring layer 103, the junction layer 105, the channel 107 and the second wiring layer 115 may be formed in a three-dimensional pillar type. The outer surface of the pillar type channel 107 may be surrounded with the current blocking layer 109 and the charge storage layer 113. By applying operating voltages to the second wiring layer 115, a charge may be injected into the charge transfer layer 113 formed at the bottom thereof. By applying a voltage over a certain level to the second wiring layer 115 to allow the burst current to flow through the charge transfer layer 113, the charges may be injected from the second wiring layer 115 to the charge storage layer 111 to program a target level of data.

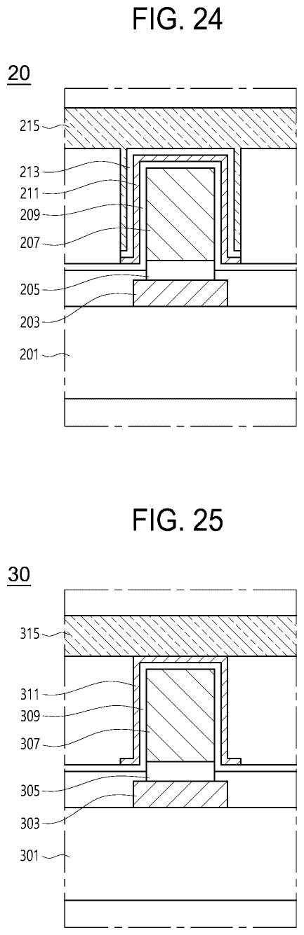

FIGS. 24 to 26 are cross-sectional views illustrating an in-memory computing device in accordance with an embodiment of the present disclosure.

Referring to FIG. 24, an in-memory computing device 20 of an embodiment may include a first wiring layer 203 formed on a first direction, such as a vertical direction, of a substrate 201, a junction layer 205 formed on the first wiring layer 203 in the first direction, and a pillar type channel 207 formed on the junction layer 205 in the first direction, a charge storage layer 211 surrounding around an upper surface and an outer surface of the channel 207, a charge transfer layer 113 surrounding around an upper surface and an outer surface of the charge storage layer 211, and a second wiring layer 215 formed to surround around an upper surface and an outer circumferential surface of the charge transfer layer 113.

A current blocking layer 209 may be formed between the pillar type channel 207 and the charge storage layer 211, but the embodiment is not limited to. The current blocking layer 209 and the charge transfer layer 113 may be formed using a high-K material.

The charge storage layer 211 may also be referred to as a charge trap layer CTL.

Compared to the in-memory computing device 10 shown in FIG. 1, a difference may be that the second wiring layer 215 may be formed to surround around the pillar type channel 207.

Referring to FIG. 25, an in-memory computing device 30 of an embodiment may include a first wiring layer 303 formed on a substrate 301 in a first direction, a junction layer 305 formed on the first wiring layer 303 in the first direction, a pillar type channel 307 formed on the junction layer 305 in the first direction, a current blocking layer 309 surrounding entirely around an upper surface and an outer surface of the channel 307, a charge storage layer 311 surrounding around an upper surface and an outer surface of the current blocking layer 309, and a second wiring layer 315 formed on the charge storage layer 311.

In an embodiment of the present disclosure, the current blocking layer 309 may be formed using a ferroelectric material and the charge storage layer 311 may be formed using a metallic material.

The in-memory computing device 30 shown in FIG. 25 may not require a formation of a charge transfer layer. When a voltage over a certain level may be applied to the second wiring layer 315, charges may be accumulated in the charge storage layer 311 by the blocking effect of the current blocking layer 309 made of ferroelectric material.

Further, a superior current transfer performance may be ensured by forming the second wiring layer 315 only on the upper portion of the channel 307.

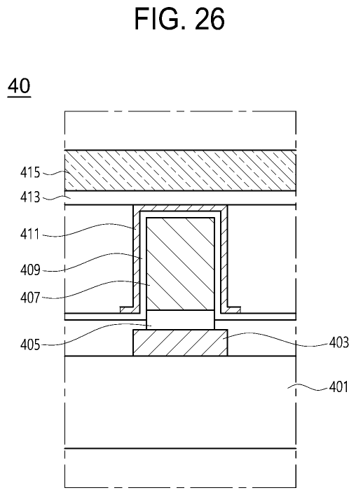

Referring to FIG. 26, an in-memory computing device 40 of an embodiment may include a first wiring layer 403 formed on a substrate 401 in a first direction, a junction layer 405 formed on the first wiring layer 403 in the first direction, a pillar type channel 407 formed on the junction layer 405 in the first direction, a current blocking layer 409 surrounding entirely around an upper surface and an outer surface of the channel 407, a charge storage layer 411 surrounding around an upper surface and an outer surface of the current blocking layer 409, a charge transfer layer 413 formed on the charge storage layer 411, and a second wiring layer 415 formed on the charge transfer layer 413.

In an embodiment of the present disclosure, the charge transfer layer 413 may be formed using a ferroelectric material. By applying a voltage over a certain level to the second wiring layer 415, charges may be injected and accumulated in the charge storage layer 411 through the charge transfer layer 413.

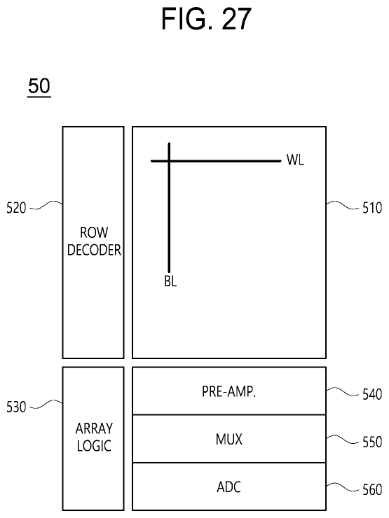

FIG. 27 is a view illustrating a computing device using an in-memory computing device in accordance with an embodiment of the present disclosure.

Referring to FIG. 27, a computing device 50 of an embodiment may include a capacitive memory cell array 510, a row decoder 520, an array logic 530, a pre-amplifier 540, a multiplexer 550 and an analog-to-digital converter (ADC) 560.

The capacitive memory cell array 510 may include a plurality of unit memory cells and can have as unit memory cells, for example, the three-dimensional capacitive in-memory computing device shown in FIG. 1 or FIGS. 24 to 26. The unit memory cells may be connected between a plurality of word lines WL and a plurality of bit lines BL.

The row decoder 520 may convert an externally provided digital input signal to an analog signal and apply the analog signal to the selected word line WL. In an embodiment of the present disclosure, the input signal may be, but is not limited to, an input characteristic vector.

The logic circuit 530 may control various operations of the computing device 50.

The pre-amplifier 540 may amplify the output signal applied to the bit lines BL of the memory cell array 510.

The multiplexer 550 may be configured to select the at least one bit line BL.

The ADC 560 may sense the analog signal applied to the selected bit line BL and convert the analog signal to a digital signal.

In the computing device 50 shown in FIG. 27, the input signal applied to the word line WL may program each memory cell of the memory cell array 510 to have a capacitance corresponding to the value of each element comprising the input signal (input characteristic vector).

By applying a read voltage to the word line WL and the bit line BL, the capacitance value of each memory cell may be accumulated by the bit line BL and outputted as a digital signal.

In-memory computation using three-dimensional pillar-type capacitor memory cells that may be integrated into a 4F2 size may enable a neural network computation on massive amounts of data with low energy while miniaturizing computing devices.

While the invention has been described in detail with reference to various embodiments, the invention is not limited to the above embodiments, but is capable of many modifications by one having ordinary skill in the art within the scope of the technical ideas of the present disclosure. Furthermore, the embodiments may be combined to form additional embodiments.

What is claimed is:

1. A three-dimensional (3D) pillar type capacitive in-memory computing device comprising:
a first wiring layer;
a junction layer formed on the first wiring layer in a first direction;
a channel formed on the junction layer along the first direction, the channel including a pillar structure;
a charge storage layer configured to surround an upper surface and an outer surface of the channel;
a charge transfer layer formed on the charge storage layer in the first direction; and
a second wiring layer formed on the charge transfer layer in the first direction.

2. The 3D pillar type capacitive in-memory computing device of claim 1, further comprising a current blocking layer formed between the channel and the charge storage layer.

3. The 3D pillar type capacitive in-memory computing device of claim 2, wherein the current blocking layer comprises a high dielectric material having a dielectric constant no less than a set value.

4. The 3D pillar type capacitive in-memory computing device of claim 1, wherein the charge storage layer comprises a conductive material.

5. The 3D pillar type capacitive in-memory computing device of claim 1, wherein the charge transfer layer is formed on a portion of the channel in the first direction.

6. The 3D pillar type capacitive in-memory computing device of claim 5, wherein the charge transfer layer comprises a dielectric material or a ferroelectric material having a dielectric constant no less than a set value.

7. The 3D pillar type capacitive in-memory computing device of claim 1, wherein the charge transfer layer is formed to surround the upper surface and the outer of the channel in the first direction.

8. The 3D pillar type capacitive in-memory computing device of claim 7, wherein the charge transfer layer comprises a high dielectric material having a dielectric constant no less than a set value.

9. The 3D pillar type capacitive in-memory computing device of claim 1, wherein the second wiring layer is formed on a portion of the channel in the first direction.

10. The 3D pillar type capacitive in-memory computing device of claim 1, wherein the second wiring layer is formed to surround the upper surface and the outer surface of the channel in the first direction.

11. The 3D pillar type capacitive in-memory computing device of claim 1, wherein the charge storage layer is configured to store a charge transferred from the charge transfer layer upon applying a voltage of a set level to the second wiring layer.

12. A 3D pillar type capacitive in-memory computing device comprising:
a first wiring layer;
a junction layer formed on the first wiring layer in a first direction;
a pillar type channel formed on the junction layer in the first direction;
a current blocking layer configured to entirely surround an upper surface and an outer surface of the channel in the first direction;
a charge storage layer configured to entirely surround an upper surface and an outer surface of the current blocking layer in the first direction; and
a second wiring layer formed on the charge storage layer in the first direction.

13. The 3D pillar type capacitive in-memory computing device of claim 12, wherein the current blocking layer comprises a ferroelectric material.

14. The 3D pillar type capacitive in-memory computing device of claim 12, wherein the charge storage layer comprises a conductive material.

15. The 3D pillar type capacitive in-memory computing device of claim 12, wherein the second wiring layer is formed on an upper region of the channel.

16. The 3D pillar type capacitive in-memory computing device of claim 12, wherein the charge storage layer is configured to store a charge transferred upon applying a voltage of a set level to the second wiring layer.

17. A method of manufacturing a 3D pillar type capacitive in-memory computing device, the method comprising:
forming a first wiring layer on a substrate;
forming a junction layer on the first wiring layer in a first direction;
forming a pillar type channel of a set height on the junction layer in the first direction;
forming a charge storage layer to surround a surface of the channel;
forming a charge transfer layer on the charge storage layer in the first direction; and
forming a second wiring layer on the charge transfer layer in the first direction.

18. The method of claim 17, further comprising forming a current blocking layer to surround the surface of the channel before forming the charge storage layer,
wherein the channel is formed to surround a surface of the current blocking layer.

19. The method of claim 18, wherein the current blocking layer comprises a high dielectric material having a dielectric constant with a set value.

20. The method of claim 17, wherein the charge storage layer comprises a conductive material.

21. The method of claim 17, wherein the charge transfer layer is formed on an upper region of the channel in the first direction.

22. The method of claim 21, wherein the charge transfer layer comprises a dielectric material or a ferroelectric material having a dielectric constant with a set value.

23. The method of claim 17, wherein the charge transfer layer is formed to surround the upper surface and the outer surface of the channel in the first direction.

24. The method of claim 23, wherein the charge transfer layer comprises a high dielectric material having a dielectric constant with a set value.

25. The method of claim 17, wherein the second wiring layer is formed on the channel in the first direction.

26. The method of claim 17, wherein the second wiring layer is formed to surround the upper surface and the outer of the channel in the first direction.

27. A computing device comprising:
a logic circuit;
a memory cell array including a plurality of unit memory cells connected between a plurality of word lines and a plurality of bit lines;
a row decoder configured to convert an externally provided digital input signal to an analog signal and to apply the analog signal to a selected word line in accordance with a control of the logic circuit;
a pre-amplifier configured to amplify an output signal applied to the bit line in accordance with a control of the logic circuit;
a multiplexer configured to select at least one of the plurality of bit lines in accordance with a control of the logic circuit; and
an analog/digital converter configured to sense an analog signal applied to a selected bit line, to convert the analog signal into a digital signal, and to output the digital signal in accordance with a control of the logic circuit,
wherein the unit memory cell comprises:
a first wiring layer;
a junction layer formed on the first wiring layer in a first direction;
a pillar type channel formed on the junction layer in the first direction;
a charge storage layer configured to surround entirely an upper surface and an outer circumferential surface of the channel;
a charge transfer layer formed on the charge storage layer in the first direction; and
a second wiring layer formed on the charge transfer layer in the first direction.

28. The computing device of claim 27, further comprising a current blocking layer formed between the channel and the charge storage layer.

29. The computing device of claim 28, wherein the current blocking layer comprises a high dielectric material having a dielectric constant with a set value.

30. The computing device of claim 27, wherein the charge storage layer comprises a conductive material.

31. The computing device of claim 27, wherein the charge transfer layer comprises a dielectric material or a ferroelectric material having a dielectric constant with a set value.
